(19) United States
(12) Patent Application Publication
(10) Pub. No.: US 2019/0097105 A1
(43) Pub. Date: Mar. 28, 2019

(54) LIGHT EMITTING DIODE ELEMENT APPARATUS AND MANUFACTURING METHOD THEREOF

(71) Applicant: Leedarson Lighting Co., Ltd., Zhangzhou (CN)

(72) Inventors: Liangliang Cao, Zhangzhou (CN); Qiyuan Wang, Zhangzhou (CN)

(21) Appl. No.: 15/860,656

(22) Filed: Jan. 3, 2018

(30) Foreign Application Priority Data
Sep. 28, 2017 (CN) 201710898123.5

(51) Int. Cl. H01L 33/62; H01L 33/54; H01L 33/60; H01L 33/50; H01L 33/64; H01L 33/48; H01L 33/00

(52) U.S. Cl. CPC H01L 33/62; H01L 33/54; H01L 33/60; H01L 33/505; H01L 2933/005; H01L 33/486; H01L 33/0095; H01L 2933/0066; H01L 33/644

(57) ABSTRACT

A light emitting diode element apparatus has a flip chip, an encapsulating structure and a fluorescent layer. The flip chip has a light emitting diode element with two chip electrodes. The two chip electrodes are set below the light emitting diode element. The upper side of the light emitting diode element emits light when the sidewall is electrically conducting. The encapsulating structure has a support seat, at least one reflective wall and two encapsulating electrodes. The two encapsulating electrodes are electrically connected to the two chip electrodes through solder, the flip chip being disposed on the support base. The at least one reflective wall directed toward the side wall of the light emitting diode element to direct light emitted from the side wall of the light emitting diode element to a predetermined direction. The present invention also discloses a method of manufacturing the light emitting diode apparatus.

### TECHNICAL FIELD

The present invention is related to a light emitting diode element apparatus and the manufacturing method, and more particularly to a light emitting diode element apparatus and the manufacturing method with improvement on an encapsulating structure.

### BACKGROUND OF THE INVENTION

Light Emitting Diode (LED) is a new generation of lighting source, because of the characteristics of high luminous efficiency, long life, energy saving, being difficult to break, and the environmental protection, light emitting diode is used in the home, office, public facilities and other lighting fields.

LED light bulbs are a new type of energy-saving light to replace traditional incandescent bulbs. The traditional incandescent light bulbs and tungsten filament light bulbs are with high energy consumption and short lifetime. Because of the depletion of natural resources, the traditional incandescent light bulbs and tungsten filament light bulbs have been gradually banned to product by the governments around the world. Then it comes to compact fluorescent lamps, the compact fluorescent lamps are designed as a replacement for the traditional incandescent light bulbs and tungsten filament light bulbs. Although the compact fluorescent lamps improve energy efficiency, the manufacturing process of the compact fluorescent lamps requires a lot of heavy metals which pollute nature, and is contrary to the general trend of environmental protection. With the rapid development of LED technology, LED lighting has become a new type of green lighting choice. LED are far superior to traditional lighting products in the working principle, energy efficiency and environmental protection. As a considerable portion of the incandescent light bulbs and the compact fluorescent lamps are still used in our daily lives, in order to reduce waste, LED lighting manufacturers must develop in line with the existing interface, the use of custom LED lighting products to make a user does not need to replace an original traditional lighting base and the case of the line may use a new generation of LED lighting products, and then an LED light bulb came out. LED light bulbs using the existing interface, that is, screw, jack way, and even in line with people's habits to imitate the incandescent bulb shape.

In addition to LED light bulbs, LED has also been widely applied to a variety of lighting apparatuses. In the lights, LED module is a key component. Inside different production technology, LED module also has a different form. As the LED module as the core source of light, whether for heat dissipation, improving the luminous efficiency or the various improvements for the development of the entire light may be a great help.

### SUMMARY OF THE INVENTION

According to an embodiment of the present invention, there is an improvement in encapsulating structure of a flip chip type light emitting diode; and further, improving the luminous efficiency and heat dissipation. As a result, the entirety of the light emitting diode light may be made more effective on the promotion.

The following describes embodiments of a light emitting diode element apparatus according to the present invention. The light emitting diode element apparatus includes a flip chip, an encapsulating structure and a fluorescent layer. The flip chip has a light emitting diode element and two chip electrodes. The two chip electrodes are set below the light emitting diode element. The upper side of the light emitting diode element emits light when the sidewall is electrically conducting. The light emitting diode elements referred to herein may be fabricated by various semiconductor techniques, such as fabricating multiple light emitting diode elements on an integrated circuit wafer and being cut. The chip electrodes referred to herein may refer to conductors that grow directly from the integrated circuit wafers, or may include a combination of solder balls and conductors.

Flip chip technology is both a chip interconnect technology, but also an ideal chip bonding technology. Flip chip technology has become a high-end apparatuses and high-density packaging applications often used in the form of packaging. Today, flip chip packaging technology is increasingly widely used. With more diversified encapsulating, flip chip packaging technology requirements also increased. At the same time, flip chip has also put forward a series of new and serious challenges to manufacturers, for the complex technology to provide packaging, assembly and testing of reliable support. The previous level of closure technology is the active area of the chip up, back to a PCB substrate and paste after the bonding, such as a wire tie and an automatic tape (TAB). FC will chip active area of the PCB substrate, through the chip array of solder bumps to achieve the chip and the substrate interconnection. The silicon wafer is mounted directly on the PCB from the silicon wafer to the surroundings, and the length of the interconnect is greatly reduced, reducing the RC delay and effectively improving the electrical performance. Obviously, the chip interconnect may provide higher I/O density. The flip-chip area is almost identical to the chip size. In all surface mount technology, the flip chip may achieve the smallest, thinnest encapsulate.

The flip chip also known as flip chip, is deposited on the I/O pad tin shot, and then flip the chip heat using the molten tin shot and ceramic chassis combined with the technology to replace the conventional wire connection, and gradually become the future of the encapsulating mainstream. Currently mainly used in high clock CPU, GPU (Graphic Processor Unit), Chipset and other products, but have been gradually extended to the production of light-emitting diode chip. Compared with the COB, the encapsulating in the form of chip structure and I/O side (solder ball) direction down, because the I/O pin is distributed in the entire chip surface, the packaging density and processing speed flip chip technology has reached peak. In particular, it may be used similar to the SMT technology to process, so the chip packaging technology and high-density installation of the final direction.

The flip chip connection are three main types, C4 (Controlled Collapse Chip Connection), DCA (Direct chip attach) and FCAA (Flip Chip Adhesive Attachment). C4 is similar to the ultrafine pitch BGA in a form with a silicon-connected solder ball array in general for a pitch of 0.23, 0.254 mm. The ball diameter is 0.102, 0.127 mm. The solder ball composition is 97Pb/3Sn. The solder balls may be distributed or partially distributed on silicon wafers.

Since the ceramic may withstand a higher reflow temperature, the ceramic is used as a substrate for C4 connection, usually on the surface of the ceramic, with a plating plate of Au or Sn pre-distributed, followed by a flip-chip connection in the form of C4. DCA and C4 are similar to an ultrafine pitch connection. DCA silicon and C4 connection are in the same silicon structure, the only difference between the two is the choice of substrate. The substrate used in DCA is a typical printed material. The solder ball component of DCA is 97Pb/Sn, and the solder on the solder plate is eutectic solder (37Pb/63Sn). For DCA because the spacing is only 0.203,0.254 mm eutectic solder leakage to the connection pad is quite difficult. Therefore, instead of solder paste leakage in this way, in the assembly before the connection to the top of the solder pad solder paste, solder on the solder volume requirements are very strict, usually than other ultra-fine pitch components used in more solder. In the connection pad 0.051,0.102 mm thick solder is pre-plated, generally slightly dome-like, must be flattened before the patch, otherwise it may affect the solder ball and the reliable positioning of the pad.

FCAA connection exists in many forms, is still in the initial stage of development. The connection between the wafer and the substrate does not use solder, but instead of glue. The bottom of the silicon in the connection may have solder balls, also use solder bumps and other structures. FCAA used in the plastic, including isotropic, anisotropic and other types, mainly depends on the actual application of the connection situation, in addition, the choices of substrate materials are usually ceramic, printed circuit board and flexible circuit board. The flip chip technology is one of today's most advanced microelectronics packaging technologies. It may increase the circuit assembly density to a new height, with the 21st century, further narrow the size of electronic products, flip chip applications may be more and more widely.

The outstanding thermal performance of the flip chip encapsulating is determined by the low thermal resistance of the heat sink and the structure. The heat generated by the chip through the heat ball feet, internal and external heat sink to achieve heat dissipation. The close contact between the heat sink and the die surface leads to a low junction temperature. To reduce the thermal resistance between the heat sink and the chip, use a high thermal colloid between the two. Making the heat within the encapsulation easier to dissipate. To further improve the thermal performance, the external heat sink may be installed directly on the heat sink to obtain a low junction temperature.

In the embodiment described above, the encapsulating structure has a support base, at least one reflective wall, and two encapsulating electrodes. The two encapsulating electrodes are electrically connected to the two chip electrodes by soldering, for example by heating the solder balls of the chip electrodes on the flip chip with hot air to complete the solder connection with the encapsulating electrodes.

The flip chip being disposed on the support base. The at least one reflective wall directed toward the side wall of the light emitting diode element to direct light emitted from the side wall of the light emitting diode element to a predetermined direction. For example, the predetermined direction may be vertically upward or offset by an angle.

In other words, the light emitting from the side walls of the light emitting diode element may be guided to the predetermined direction by one or more reflections. The predetermined direction may be set according to the characteristics of the light emitting diode element. For example, the predetermined direction may be adjusted according to the angle at which the side walls of the light emitting diode elements emit light. For example, the height and tilt angle of the reflective wall of the encapsulating structure may be designed and optimized for different light emitting diode elements so that most of the light may be guided to the desired direction and increase the overall light efficiency.

In addition, since lamps are usually set with multiple light emitting diode element apparatuses in one light source plate. The locations of these light emitting diode element apparatuses in the circuit board are different. With the design requirements of light, the lighting directions of light emitting diode element apparatuses may different. At this time, the light emitting characteristics of the light emitting diode element apparatus may be fine-tuned by adjusting the horizontal angle of the carrier and the angle of the reflection wall. In other words, on a light source board, more than two kinds of light emitting diode element apparatuses may be set. The different light emitting diode element apparatuses may use the same light emitting diode elements, but the parameters of the angle or height of the reflective wall or carrier have different values.

In other words, at the time of manufacture, the overall optimization of the light may be achieved by selecting the light emitting diode element apparatus means for the light fixture characteristics to be matched with the light emitting diode element apparatus and the position of the light emitting diode element apparatus.

In addition, in the above-described embodiment, a fluorescent layer may be set. The fluorescent layer selects an appropriate fluorescent material according to the desired light emission characteristics and when set, directs the light emitting diode element to emit and react with the reflected light to emit the output light of the predetermined spectrum.

According to one embodiment of the present invention, the encapsulating structure may have four reflective walls. The four reflective walls forming an accommodating space. The fluorescent layer being filled in the accommodating space. In other words, the light emitting diode element is placed in a base corresponding to the valley. The light emitting from the side wall of the light emitting diode element is reflected upward through the surrounding reflective wall.

At present the more common light emitting diode elements are usually made rectangular cubes, that is, with four side walls. The four reflective walls facing the four side walls of the light emitting diode element respectively, reflecting light from the four side walls in a direction above the light emitting diode element.

Of course, in addition to the quadrilateral, other shapes of the reflective wall, such as hexagonal, etc. may also be used as a design choice to meet the different light emitting diode elements of the shape. For example, the light emitting diode element may be hexagonal or circular, and the reflective wall may also be configured accordingly. In addition, when the sidewall of the light emitting diode element is non-perpendicular but has a certain arc or angle, the reflective wall may also be arranged so that the light of the sidewall of the light emitting diode element may be diverted to the desired direction.

It is to be noted that this desired direction does not necessarily need to be just above the light emitting diode element. With the characteristics of different lights and needs, may adjust the reflection of the wall angle, radians and other parameters, to adjust the path of the light adjustment.

For example, the inclination angles of the four reflective walls with respect to the side walls of the light emitting diodes are between 30 degrees to 60 degrees, for example 45 degrees. In other words, if the light of the sidewall of the light emitting diode is emitted perpendicularly to the straight side wall, it is just above the light emitting diode element when it is projected onto the radiation wall.

In addition, in another embodiment, the side profile of the reflective wall is curved rather than straight. In the requirements of some embodiments, the bottom curvature of the reflective wall is greater than the upper portion of the reflective wall. Typically, such a setting may direct most of the light to the top.

As described above, the reflective wall does not have to be a quadrilateral, for example, the reflective wall of the encapsulating structure may be designed to be narrowly wide. In other words, it is not necessary to arrange four reflective walls with respect to the rectangular light emitting diode element.

Another approach also includes forming the reflective wall of the encapsulating structure into a bowl-shaped structure with an upward opening. The design is relatively easy to manufacture through the mold, and may produce good optical characteristics.

In addition, in some embodiments, the surface of the reflective wall of the encapsulating structure is set to be adapted to reflect the light of the material. For example, a reflective layer, such as a lens, may be attached. Other practices include providing a reflective material on the surface of the reflective wall, for example, coated with a light-colored pigment coating having a relatively good reflectance, such as a white or silver coating.

In a further embodiment, in addition to guiding the light, the reflective wall may also be set with heat dissipation materials to assist in overall heat dissipation efficiency.

Further, in addition to the reflective wall, the encapsulating structure may have an outer wall, the reflective wall side is connected to the outer wall, the other side of the reflective wall is connected to the support base, and the middle of the outer wall and the reflective wall is hollow. In other words, the encapsulation has a hollow feature to save material, may also help to achieve the effect of cooling.

In order to further increase the heat dissipation effect, in such an embodiment,

the hollow portion in the middle of outer wall and the reflective wall may be further filled with the heat dissipation materials.

In some embodiments, the encapsulating electrode is connected to a circuit board electrode of a circuit board to provide power to the chip electrode such that the light emitting diode element emits light. In particular, the encapsulating electrode is disposed in the support base. The first side of the encapsulating electrode faces the chip electrode, and the other side of the encapsulating electrode faces the circuit board electrode. In other words, the encapsulation electrode assists as a conductive medium between the circuit board and the light emitting diode element.

In some embodiments, the support base is made by a plastic material and the encapsulating electrode is secured to the support base by injection molding. In particular, electrodes may be patterned on a metal plate or electrodes may be fabricated in other ways, and then put the electrode into the injection molding machine, so that when the plastic material packaging structure is made, the packaging electrode has been embedded in the location of the reservation to reduce costs and increase product stability.

In some embodiments, the width of the encapsulation structure is between 0.8 millimeter to 3 millimeters and the height is between 0.1 millimeter to 1.5 millimeters. Also, it is preferable that the width of the encapsulating structure is between 1.5 millimeters to 2.5 millimeters and the height is between 0.3 millimeter to 0.6 millimeter. The parameter setting has been tested with good heat to reflect the effect.

In addition, the embodiments of the present invention also include a method of manufacturing a light emitting diode element apparatus is characterized in the following steps.

There is an encapsulating structure array with multiple encapsulating structures. Each encapsulating structure has a support base, at least one reflective wall, and two encapsulating electrodes.

Multiple flip chips are respectively arranged in the support base. The flip chip has a light emitting diode element and two chip electrodes. The two chip electrodes are set below the light emitting diode element. The upper side of the light emitting diode element emits light when the sidewall is electrically conducting.

The two encapsulating electrodes are respectively electrically connected with the two chip electrodes through solder. The at least one reflective wall directed toward the side wall of the light emitting diode element to direct light emitted from the side wall of the light emitting diode element to a predetermined direction.

The multiple encapsulating structures are removed from the encapsulating structure array. For example, individual light emitting diode element apparatuses are obtained by way of cutting.

In one embodiment, the method further includes bonding the two encapsulating electrodes to the solder balls on the two chip electrodes, and electrically connecting the solder by heating the solder balls.

The present invention has the advantages of improving the light emitting diode related packaging structure and improving the technical problems such as luminous efficiency and heat dissipation, so that the whole of the light emitting diode lights may achieve greater efficiency.

### BRIEF DESCRIPTION OF THE DRAWINGS

FIG. 1 illustrates a schematic perspective view of an embodiment of a light emitting diode element apparatus arrangement according to the present invention.

FIG. 2 illustrates a side cross-sectional view of an embodiment of a light emitting diode element apparatus arrangement according to the present invention.

FIG. 3A illustrates a schematic top view of a configuration of a reflective wall.

FIG. 3B provides a schematic cross-sectional view of FIG. 3A.

FIG. 4 provides another design of the reflective wall.

FIG. 5 illustrates the use of different parameters on the display of light emitting diode element apparatus.

FIG. 6 illustrates a flow chart of an apparatus for fabricating a light emitting diode element apparatus.

### DETAILED DESCRIPTION

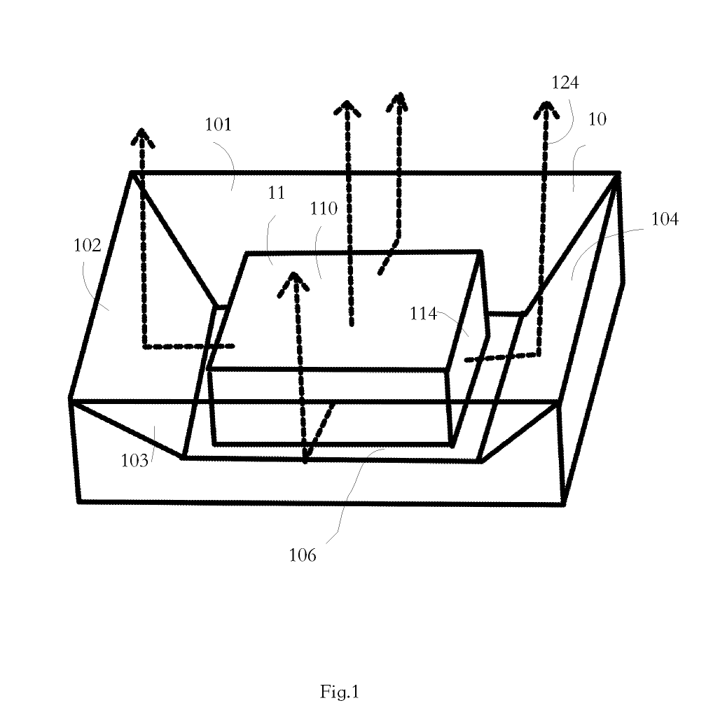

Please refer to FIG. 1, FIG. 1 illustrates a schematic perspective view of an embodiment of a light emitting diode element apparatus arrangement according to the present invention. In this embodiment, the light emitting diode element apparatus has a flip chip 11, an encapsulating structure 10 and a fluorescent layer (not shown).

The flip chip 11 is set on the support base 106 of the encapsulating structure 10. The encapsulating structure 10 has a reflective wall.

The flip chip 11 has a light emitting diode element and two chip electrodes. The two chip electrodes are set below the light emitting diode element. The upper side of the light emitting diode element emits light when the sidewall is electrically conducting, as indicated by the dotted line 124 of FIG. 1. The light emitting diode elements remained here may be fabricated by various semiconductor techniques, such as fabricating multiple light emitting diode elements on an integrated circuit wafer and being cut. The chip electrodes remained here may refer to conductors that grow directly from the integrated circuit wafers, or may include a combination of solder balls and conductors.

In this embodiment, the encapsulating structure 10 has a support base 106, four reflective walls 101, 102, 103, 104 and two encapsulating electrodes. The two encapsulating electrodes are electrically connected to the two chip electrodes by soldering, for example by heating the solder balls of the chip electrodes on the flip chip with hot air to complete the solder connection with the encapsulating electrodes.

The flip chip 11 is set on the support base 106. The four reflective walls 101, 102, 103, 104 are directed towards the sidewalls of the light emitting diode element, such as the sidewalls 114 to direct light emitted from the side walls of the light emitting diode element to a predetermined direction 124. For example, the predetermined direction may be vertically upward or offset by an angle.

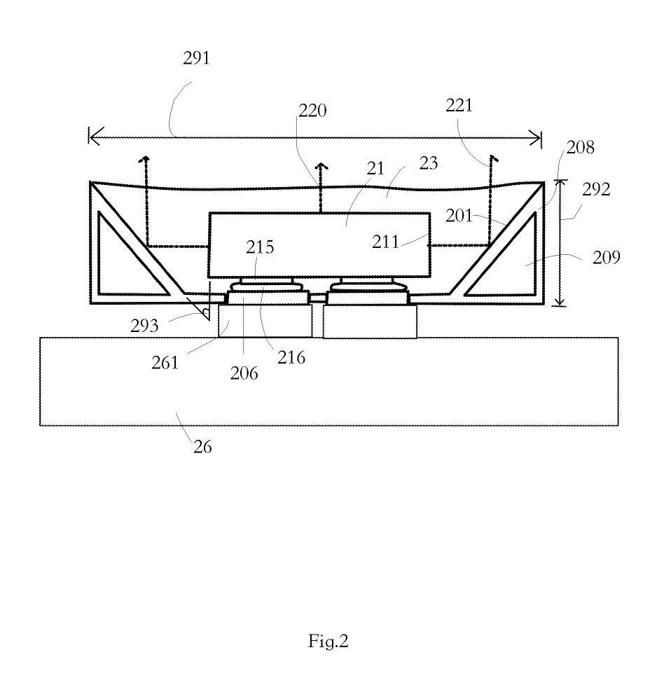

Next, please refer to FIG. 2, FIG. 2 illustrates a cross-sectional view of the embodiment of FIG. 1. In FIG. 2, the flip chip 21 has a chip electrode 215. A solder bump 216 is attached to the chip electrode 215 for connecting the encapsulating electrode 206 of the encapsulating structure. The encapsulating electrode 206 is further connected to the electrode 261 of the light source plate 26 to receive a desired current to drive the flip chip to emit light.

After the current is connected, the upper 220 of the flip chip 21 emits light. In addition, the side wall 211 of the flip chip 21 also emits light. The light of the side wall 211 is reflected by the reflective wall 201 of the encapsulating structure so that light is guided into the desired direction 221. In this example, the angle 293 between the reflective wall and the side wall may be between thirty degrees and sixty degrees, for example forty-five degrees.

In this example, the width 291 of the encapsulating structure may be between 0.8 millimeter to 3 millimeters and the height 292 may be between 0.1 millimeter to 1.5 millimeters. Also, it is preferable that the width of the encapsulating structure is between 1.5 millimeters to 2.5 millimeters and the height is between 0.3 millimeter to 0.6 millimeter. The parameter setting has been tested with good heat to reflect the effect.

In addition, a hollow structure 209 may be set between the reflective wall 201 and the outer wall 208, and the heat dissipation material may be filled to assist in heat dissipation.

After the light passes through the fluorescent layer 23, the light of the desired spectrum is emitted.

In other words, the light emitting from the side walls of the light emitting diode element may be guided to the predetermined direction by one or more reflections. The predetermined direction may be set according to the characteristics of the light emitting diode element. For example, the predetermined direction may be adjusted according to the angle at which the side walls of the light emitting diode elements emit light. For example, the height and tilt angle of the reflective wall of the encapsulating structure may be designed and optimized for different light emitting diode elements so that most of the light may be guided to the desired direction and increase the overall light efficiency.

According to one embodiment of the present invention, the encapsulating structure may have four reflective walls. The four reflective walls forming an accommodating space, the fluorescent layer being filled in the accommodating space. In other words, the light emitting diode element is placed in a base corresponding to the valley. The light emitted from the side wall of the light emitting diode element is reflected upward through the surrounding reflective wall.

At present, the more common light emitting diode elements are usually made rectangular cubes with the four side walls. The four reflective walls facing the four side walls of the light emitting diode element respectively, reflecting light from the four side walls in a direction above the light emitting diode element.

Of course, in addition to the quadrilateral, other shapes of the reflective wall, such as hexagonal, etc. may also be used as a design choice to meet the different light emitting diode elements of the shape. For example, the light emitting diode element may be hexagonal or circular, and the reflective wall may also be configured accordingly. In addition, when the sidewall of the light emitting diode element is non-perpendicular but has a certain arc or angle, the reflective wall may also be arranged so that the light of the sidewall of the light emitting diode element may be diverted to the desired direction.

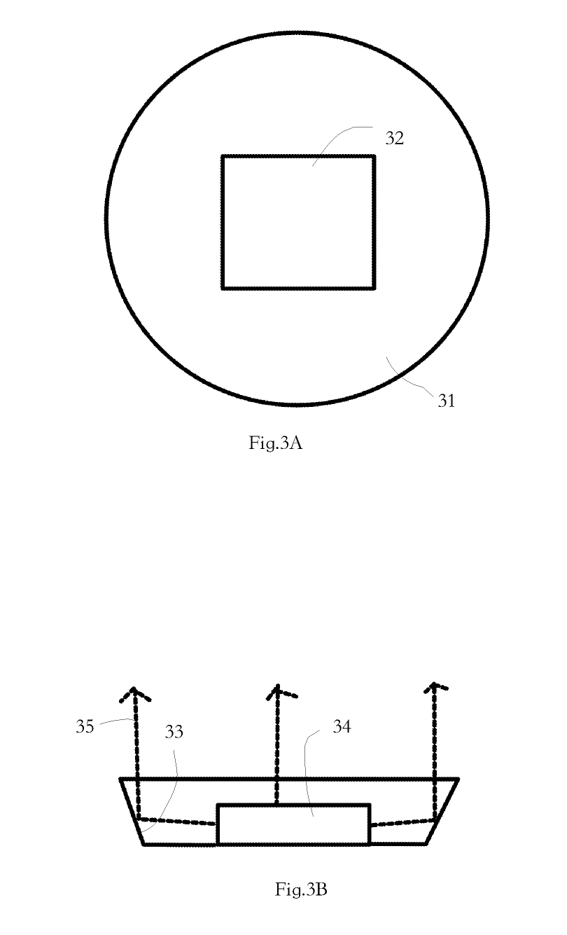

Please refer to FIG. 3A, FIG. 3A illustrates a schematic top view of a configuration of a reflective wall. In FIG. 3A, the reflective wall 31 is tapered and the flip chip 32 is a rectangular parallelepiped.

FIG. 3B is a side view of FIG. 3A. The light from the side wall of the flip chip 34 passes through the reflective wall 33 to direct the light into the desired direction 35.

It is to be noted that the desired direction does not necessarily need to be just above the light emitting diode element. With the characteristics of different lights and needs may adjust the reflection of the wall angle, radians and other parameters, to adjust the path of the light adjustment.

For example, the inclination angles of the four reflective walls with respect to the side walls of the light emitting diodes are between thirty degrees and sixty degrees, for example forty-five degrees. In other words, if the light of the sidewall of the light emitting diode is emitted perpendicularly to the straight side wall, just above the light emitting diode element when projected onto the radiation wall.

In addition, in another embodiment, the side profile of the reflective wall is curved rather than straight. In the requirements of some embodiments, the bottom curvature of the reflective wall is greater than the upper portion of the reflective wall. Typically, such a setting may direct most of the light to the top.

As described above, the reflective wall does not have to be a quadrilateral, for example, the reflective wall of the encapsulating structure may be designed to be narrowly wide. In other words, it is not necessary to arrange the four reflective walls with respect to the rectangular light emitting diode element.

Another approach also includes forming the reflective wall of the encapsulating structure into a bowl-shaped structure with an upward opening. The design is relatively easy to manufacture through the mold, and may produce good optical characteristics.

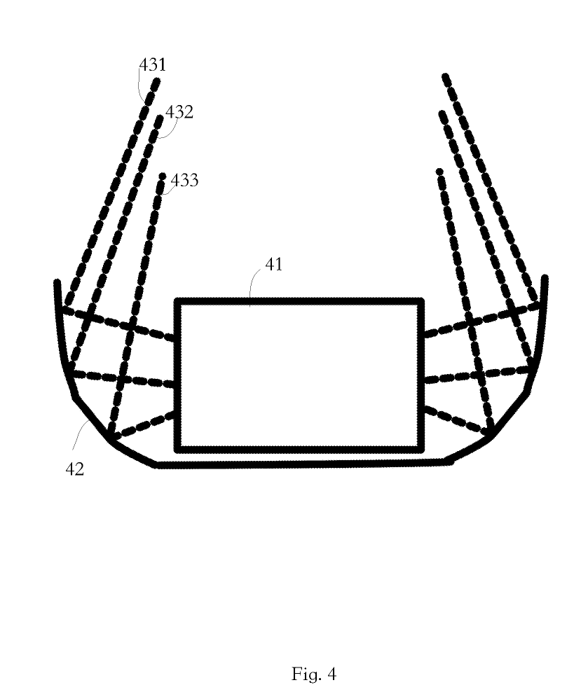

Please refer to FIG. 4, FIG. 4 illustrates a side view of another embodiment of the reflective wall 42. In FIG. 4, the side walls of the flip chip 41 emit light having multiple different reflection results 431, 432, 433 through a bowl having a lower slope than the upper side.

In addition, since the light is usually set with multiple light emitting diode element apparatuses in one light source plate. The multiple light emitting diode element apparatuses in this circuit board location are different, with the design requirements of lights, the light directions of the light emitting diode element apparatuses may different. At this time, the light emitting characteristics of the light emitting diode element apparatus may be fine-tuned by adjusting the horizontal angle of the carrier and the angle of the reflection wall. In other words, on a light source board, more than two kinds of light emitting diode element apparatuses may be set. The different light emitting diode element apparatuses may use the same light emitting diode elements, but the parameters of the angle or height of the reflective wall or carrier have different values.

In other words, at the time of manufacture, the overall optimization of the light may be achieved by selecting the light emitting diode element apparatus means for the light fixture characteristics to be matched with the light emitting diode element apparatus and the position of the light emitting diode element apparatus.

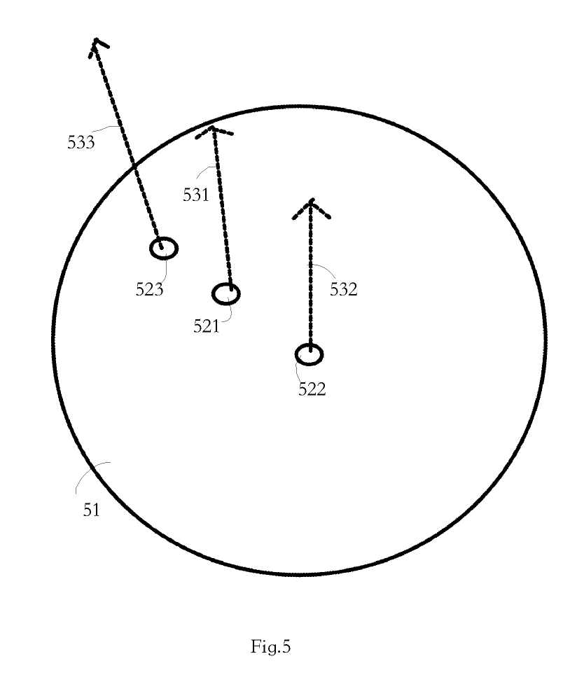

Please refer to FIG. 5, FIG. 5 illustrates a light fixture having multiple parameter light emitting diode apparatus is arranged on a light source board 51. In FIG. 5, depending on the arrangement position, the light emitting diode element apparatuses 521, 522, 523 may be set by different parameters such as the angle of the carrier and the reflection wall to produce different light directions 531, 532, In other words, may adjust the encapsulating structure to fine tune the luminous results of the entire light, the overall luminous efficiency with the effect of optimizing the adjustment.

In addition, in the above described embodiment, a fluorescent layer may be set. The fluorescent layer selects an appropriate fluorescent material according to the desired light emission characteristics and, when set, directs the light emitting diode element to emit and react with the reflected light to emit the output light of the predetermined spectrum.

In addition, in some embodiments, the surface of the reflective wall of the encapsulating structure is set to be adapted to reflect the light of the material. For example, a reflective layer, such as a lens, may be attached. Other practices include providing a reflective material on the surface of the reflective wall, for example, having a coating with light colors, to make it has higher reflectance, such as a white or silver coating.

In other embodiments, in addition to guiding the light, the reflective wall may also be set with a heat dissipation material to assist in overall heat dissipation.

Further, in addition to the reflective wall, the encapsulating structure may have an outer wall, the reflective wall side is connected to the outer wall, the other side of the reflective wall is connected to the support base, and the middle of the outer wall and the reflective wall is hollow. In other words, the encapsulating has a hollow feature to save material, may also help to achieve the effect of cooling.

In order to further increase the heat dissipation effect, in such an embodiment, the outer wall and the hollow portion in the middle of the reflective wall may be further filled with the heat dissipation material.

In some embodiments, the encapsulating electrode is connected to a circuit board electrode of a circuit board to provide power to the chip electrode such that the light emitting diode element emits light. In particular, the encapsulating electrode is disposed in the support base. The first side of the encapsulating electrode faces the chip electrode, and the other side of the encapsulating electrode faces the circuit board electrode. In other words, the encapsulation electrode assists as a conductive medium between the circuit board and the light emitting diode element.

In some embodiments, the support base is a plastic material and the encapsulating electrode is secured to the support base by injection molding. In particular, electrodes may be patterned on a metal plate or electrodes may be fabricated in other ways, and then put the electrode into the injection molding machine, so that when the plastic material packaging structure is made, the packaging electrode has been embedded in the location of the reservation to reduce costs and increase product stability.

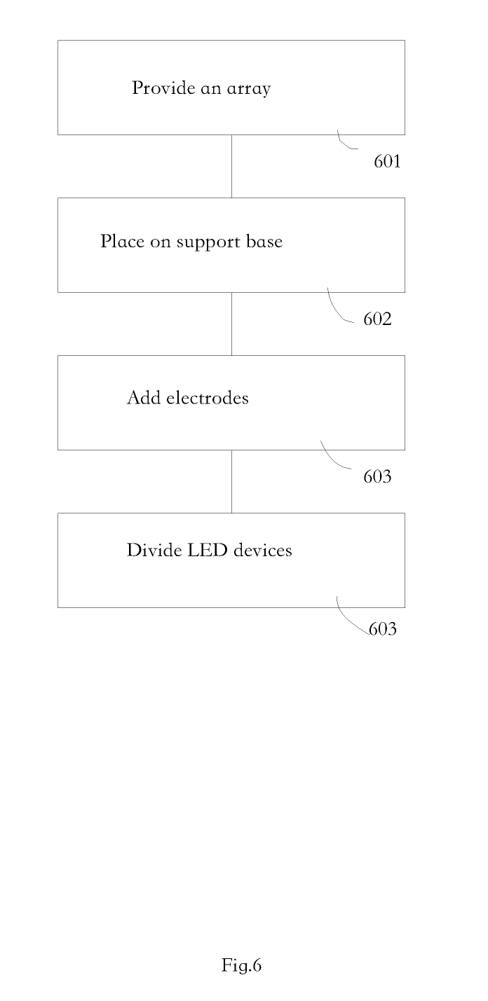

Please refer to FIG. 6, FIG. 6 illustrates a method of manufacturing a light emitting diode element apparatus is characterized in the following steps.

Provide an encapsulating structure array. (step 601) The encapsulating structure array has multiple encapsulating structures. Each encapsulating structure has a support base, at least one reflective wall, and two encapsulating electrodes.

Multiple flip chips are respectively arranged in the support base. (step 602) The flip chip has a light emitting diode element and two chip electrodes. The two chip electrodes are mounted below the light emitting diode element. The upper side of the light emitting diode element emits light when the sidewall is electrically conducting.

The two encapsulating electrodes are respectively electrically connected with the two chip electrodes through solder. (step 603) The at least one reflective wall directed toward the side wall of the light emitting diode element to direct light emitted from the side wall of the light emitting diode element to a predetermined direction.

The multiple encapsulating structures are removed from the encapsulating structure array. (step 604) For example, individual light emitting diode element apparatuses are obtained by way of cutting.

In one embodiment, the method further includes bonding the two encapsulating electrodes to the solder balls on the two chip electrodes, and electrically connecting the solder by heating the solder balls.

In addition to the above described embodiments, various modifications may be made and within the spirit of the same invention, the various designs may be made by the skilled in the art are susceptible in the protection range of the present invention.

1. A light emitting diode element apparatus, comprising:
a flip chip, wherein the flip chip has a light emitting diode element and two chip electrodes, the two chip electrodes are set below the light emitting diode element, the upper side of the light emitting diode element emits light when the sidewall is electrically conducting;
an encapsulating structure, wherein the encapsulating structure has a support base, at least one reflective wall, and two encapsulating electrodes, the two encapsulating electrodes are respectively electrically connected to the two chip electrodes, and the flip chip is set on the support base, at least one reflective wall directed towards the side wall of the light emitting diode element, directing light emitting from the side wall of the light emitting diode element to a predetermined direction; and
a fluorescent layer, directing the light emitting from the light emitting diode element with the reflected light to emit the output light of a predetermined spectrum.

2. The light emitting diode element apparatus of claim 1, wherein the encapsulating structure has four reflective walls, the four reflective walls form an accommodating space, and the fluorescent layer is filled in the accommodating space.

3. The light emitting diode element apparatus of claim 1, wherein the light emitting diode element has four side walls, the four reflective walls face the four side walls of the light emitting diode element respectively, and reflect light from the four side walls in a direction above the light emitting diode element.

4. The light emitting diode element apparatus of claim 3, wherein the inclination angles of the four reflective walls with respect to the side walls of the light emitting diodes are between 30 degrees to 60 degrees.

5. The light emitting diode element apparatus of claim 1, wherein the side profile of the reflective wall is curved.

6. The light emitting diode element apparatus of claim 5, wherein the bottom curvature of the reflective wall is greater than the upper portion of the reflective wall.

7. The light emitting diode element apparatus of claim 1, wherein the reflective wall of the encapsulating structure is designed to be narrowly wide.

8. The light emitting diode element apparatus of claim 1, wherein the reflective wall of the encapsulating structure become a bowl-shaped structure with an upward opening.

9. The light emitting diode element apparatus of claim 1, wherein the surface of the reflective wall of the encapsulating structure is set to be adapted to reflect the light of the material.

10. The light emitting diode element apparatus of claim 9, wherein the reflective wall is coated with a light-colored pigment coating.

11. The light emitting diode element apparatus of claim 1, wherein the reflective wall is set with heat dissipation materials.

12. The light emitting diode element apparatus of claim 1, wherein the encapsulating structure has an outer wall, the reflective wall side is connected to the outer wall, the other side of the reflective wall is connected to the support base, and the middle of the outer wall and the reflective wall is hollow.

13. The light emitting diode element apparatus of claim 1, wherein the hollow portion in the middle of outer wall and the reflective wall is filled with the heat dissipation materials.

14. The light emitting diode element apparatus of claim 1, wherein the encapsulating electrode is connected to a circuit board electrode of a circuit board to provide power to the chip electrode to make the light emitting diode element emit light.

15. The light emitting diode element apparatus of claim 14, wherein the encapsulating electrode is disposed in the support base, the first side of the encapsulating electrode faces the chip electrode, and the other side of the encapsulating electrode faces the circuit board electrode.

16. The light emitting diode element apparatus of claim 14, wherein the support base is a plastic material and the encapsulating electrode is secured to the support base by injection molding.

17. The light emitting diode element apparatus of claim 1, wherein the width of the encapsulation structure is between 0.8 millimeter to 3 millimeters and the height is between 0.1 millimeter to 1.5 millimeters.

18. The light emitting diode element apparatus of claim 16, wherein the width of the encapsulating structure is between 1.5 millimeters to 2.5 millimeters and the height is between 0.3 millimeter and 0.6 millimeter.

19. A manufacturing method of the light emitting diode element apparatus, comprising:
providing an encapsulating structure array, the encapsulating structure array having a plurality of encapsulating structures, each encapsulating structure having a support base, at least one reflective wall, and two encapsulating electrodes;
arranging multiple flip chips respectively in the support base, the flip chip having a light emitting diode element and two chip electrodes, the two chip electrodes being set below the light emitting diode element, the upper side of the light emitting diode element emitting light when the sidewall being electrically conducting;
connecting the two encapsulating electrodes with the two chip electrodes through solder respectively and electrically, at least one reflective wall directed toward the side wall of the light emitting diode element to direct light emitted from the side wall of the light emitting diode element to a predetermined direction; and
removing the multiple encapsulating structures from the encapsulating structure array.

20. The manufacturing method of the light emitting diode element apparatus of claim 19, further comprising bonding the two encapsulating electrodes to the solder balls on the two chip electrodes, and electrically connecting the solder by heating the solder balls.
